(19) United States
(12) Patent Application Publication
(10) Pub. No.: US 2025/0096119 A1
(43) Pub. Date: Mar. 20, 2025

(54) SEMICONDUCTOR DEVICE, RESISTIVE DEVICE, AND METHOD OF OBTAINING ELECTRICAL CHARACTERISTICS OF SEMICONDUCTOR DEVICE

(71) Applicant: TAIWAN SEMICONDUCTOR MANUFACTURING COMPANY LTD., HSINCHU (TW)

(72) Inventors: WEI-LIN LAI, HSINCHU CITY (TW); SZU-LIN LIU, HSINCHU CITY (TW)

(21) Appl. No.: 18/467,684

(22) Filed: Sep. 14, 2023

(51) Int. Cl. H01L 23/522; H01L 21/66

(52) U.S. Cl. CPC H01L 23/5228; H01L 22/14; H01L 23/5226

(57) ABSTRACT

The present disclosure provides a resistive device. The resistive device includes a conductive structure, a row of first vias, and a row of second vias. The conductive structure has a first side and a second side opposite to the first side, and a first surface connected between the first side and the second side. The row of first vias extends through the conductive structure in a first direction substantially perpendicular to the first surface. The row of first vias is closer to the first side than the second side. The row of second vias extends through the conductive structure in the first direction. The row of second vias is disposed between the first side of the conductive structure and the row of first vias.

### BACKGROUND

Measuring electrical characteristics of semiconductor structures has always been an important procedure in manufacturing, yet the accuracy of these measurements may be influenced by inherent variations.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1 is a schematic diagram of a substrate and a measurement tool, in accordance with some embodiments.

FIG. 2 is a schematic diagram of a relationship between components of a semiconductor device, in accordance with some embodiments.

FIG. 3 is a schematic diagram of a relationship between components of a semiconductor device, in accordance with some embodiments.

FIG. 4 is a schematic diagram of a relationship between components of a semiconductor device, in accordance with some embodiments.

FIG. 5 is a flowchart showing a method of obtaining electrical characteristics of components of a semiconductor device, in accordance with some embodiments.

FIG. 6 is a schematic diagram of a substrate and a measurement tool, in accordance with some embodiments.

FIG. 7 is a schematic diagram of a top view of a component of a semiconductor device, in accordance with some embodiments.

FIG. 7A is a schematic diagram of a cross-sectional view of a component of a semiconductor device, in accordance with some embodiments.

FIG. 8 is a schematic diagram of a top view of a component of a semiconductor device, in accordance with some embodiments.

FIG. 9 is a schematic diagram of the measurement of a component of a semiconductor device, in accordance with some embodiments.

FIG. 9A is a circuit diagram equivalent to the measurement of a component of a semiconductor device in FIG. 9.

FIG. 10 is a flowchart showing a method of obtaining electrical characteristics of components of a semiconductor device, in accordance with some embodiments.

FIG. 11 is a schematic diagram of the measurement of a component of a semiconductor device, in accordance with some embodiments.

FIG. 11A is a circuit diagram equivalent to the measurement of a component of a semiconductor device in FIG. 11.

FIG. 11B is a schematic diagram of a relationship between components of a semiconductor device, in accordance with some embodiments.

FIG. 12 is a flowchart showing a method of obtaining electrical characteristics of components of a semiconductor device, in accordance with some embodiments.

FIG. 13 is a flowchart showing a testing method, in accordance with some embodiments.

FIG. 14A is a plot of correlation values between a first variable and a second variable, in accordance with some embodiments.

FIG. 14B illustrates determining the retention and/or removal of correlation values, in accordance with some embodiments.

FIG. 15 is a plot of a variable versus a resistance contribution, in accordance with some embodiments.

FIG. 16 is a schematic diagram of arrays of a substrate, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

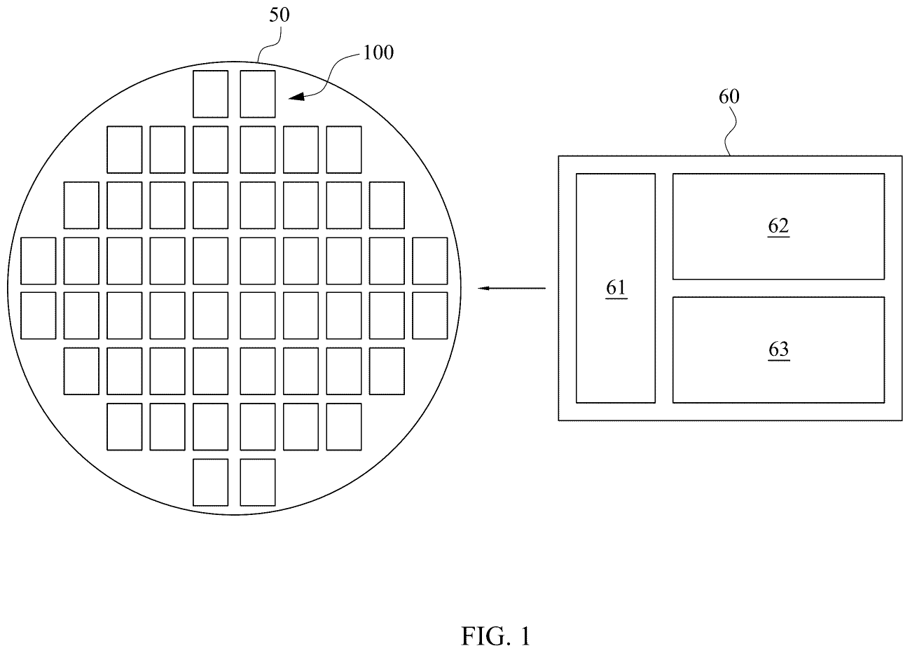

FIG. 1 is a schematic diagram of a substrate 50 and a measurement tool 60, in accordance with some embodiments.

The substrate 50 includes a plurality of semiconductor devices 100. The semiconductor devices 100 are distributed across the substrate 50. The semiconductor devices 100 may be separated from each other by a scribe line. The substrate 50 may be subjected to the singulation process to divide the semiconductor devices 100 into different units. The substrate 50 may be a wafer. The semiconductor devices 100 may be dies. The semiconductor devices 100 include integrated circuits. The semiconductor devices 100 may include one or more processing elements and one or more memory elements electrically connected to the processing elements. The processing element(s) and the memory element(s) may be divided from or originate in a monolithic processing unit (e.g., a CPU, a MPU, a GPU, an MCU, an ASIC, or the like). In some embodiments, the processing element may be a CPU chiplet, an MCU chiplet, a GPU chiplet, an ASIC chiplet, or the like. The semiconductor devices 100 may include passive elements, e.g., resistors, capacitors, inductors, or the like.

In some embodiments, the substrate 50 may be a tape and the semiconductor devices 100 may be divided units that are attached to the tape.

The measurement tool 60 is configured to detect, measure, or monitor the electrical characteristics of the substrate 50 (or the semiconductor devices 100). The measurement tool 60 may detect, measure, or monitor a portion of the semiconductor devices 100, that is, in a sampling manner. The measurement tool 60 may detect, measure, or monitor the entire group of semiconductor device 100. The measurement tool 60 can be further configured to calculate electrical characteristics of the substrate 50 or the semiconductor devices 100. The measurement tool 60 includes a probe apparatus 61, an analysis apparatus 62, and a memory 63. The probe apparatus 61 is coupled with the analysis apparatus 62. The analysis is coupled with the memory 63. The memory 63 is coupled with the probe apparatus 61. The probe apparatus 61, the analysis apparatus 62, and the memory 63 may be connected through wired or wireless means.

The probe apparatus 61 applies stimulus over one or more of the semiconductor devices 100 or the test patterns on the scribe lines of the substrate 50. The stimulus may include voltage, current, or illumination. The probe apparatus 61 detects and measures electrical signals from the substrate 50 (e.g., one or more of the semiconductor devices 100 or the test patterns on the scribe lines), in response to the stimulus. The electrical signals may include voltage or current. The probe apparatus 61 can move across the substrate 50 to apply stimulus to designated locations. Therefore, designated semiconductor devices 100 can be detected and measured. In particular, a part of the integrated circuit in the semiconductor device 100, e.g., one or more designated resistors, can be detected and measured at the same time or in sequence.

The probe apparatus 61 transmits the electrical signals to the analysis apparatus 62. In response to the electrical signals, the analysis apparatus 62 is configured to analyze the electrical characteristics of one or more of the semiconductor devices 100 or the test patterns on the scribe lines of the substrate 50. The analysis apparatus 62 may include a computer system, module, or software/program, used for the analysis. The electrical characteristics may include resistance, capacitance, inductance, threshold voltage, breakdown voltage, on-current, or the like.

The memory 63 stores the software/program/algorithm used in the probe apparatus 61 and the analysis apparatus 62. The memory 63 stores the electrical characteristics generated by the analysis apparatus 62.

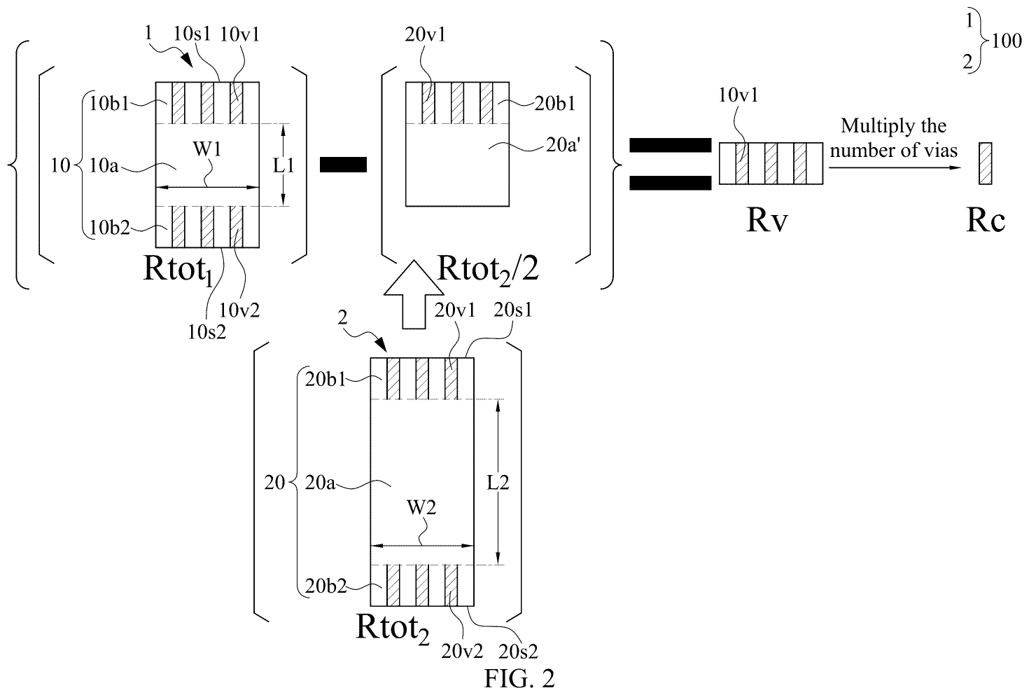

FIG. 2 is a schematic diagram of a relationship between components of the semiconductor device 100, in accordance with some embodiments. The semiconductor device 100 is one of the semiconductor devices 100 of the substrate 50 in FIG. 1. The semiconductor device 100 of FIG. 2 may be detected, measured, or monitored by the measurement tool 60.

The semiconductor device 100 includes a component (e.g., a resistor or resistive device) 1 and a component (e.g., a resistor or resistive device) 2. The component 1 includes a conductive structure 10. The conductive structure 10 includes a conductive layer 10a, a via region 10b1, and a via region 10b2. The conductive layer 10a is disposed between the via regions 10b1 and 10b2. The dashed line between the conductive layer 10a and one of the via regions 10b1 and 10b2 is merely used to indicate the locations thereof. There may be no boundary/interface between the conductive layer 10a and one of the via regions 10b1 and 10b2. The via regions 10b1 and 10b2 may be made from a conductive material. The via regions 10b1 and 10b2 may be part of the conductive layer 10a.

The conductive layer 10a has a length L1 and a width W1 perpendicular to the length L1. The component 1 includes a plurality of conductive vias (or a number of conductive vias) 10v1 disposed in the via region 10b1 and a plurality of conductive vias (or a number of conductive vias) 10v2 disposed in the via region 10b2. The conductive vias 10v1 may include a row of vias (or conductive vias) arranged in the same direction as the width W1. The conductive vias 10v2 may include a row of vias arranged in the same direction as the width W1. The conductive structure 10 has a first side 10s1 and a second side 10s2 opposite to the first side 10s1. The row of the vias 10v1 is closer to the first side 10s1 than the second side 10s2. The row of the vias 10v2 is closer to the second side 10s2 than the first side 10s1. In other words, the conductive vias 10v1 and 10v2 are disposed adjacent to the opposite sides 10s1 and 10s2, respectively, of the conductive structure 10 (or the component 1).

The conductive structure 10 and conductive vias 10v1 and 10v2 may be made of metal, e.g., Cu, Ti, Au, or the like.

The component 2 includes a conductive structure 20. The conductive structure 20 includes a conductive layer 20a, a via region 20b1, and a via region 20b2. The conductive layer 20a is disposed between the via regions 20b1 and 20b2. The dashed line between the conductive layer 20a and one of the via regions 20b1 and 20b2 is merely used to indicate the locations. There may be no boundary/interface between the conductive layer 20a and one of the via regions 20b1 and 20b2. The via regions 20b1 and 20b2 may be made from a conductive material. The via regions 20b1 and 20b2 may be part of the conductive layer 20a.

The conductive layer 20a has a length L2 and a width W2 perpendicular to the length L2. The component 2 includes a plurality of conductive vias (or a number of conductive vias) 20v1 disposed in the via region 20b1 and a plurality of conductive vias (or a number of conductive vias) 20v2 disposed in the via region 20b2. The conductive vias 20v1 may include a row of vias (or conductive vias) arranged in the same direction as the width W2. The conductive vias 20v2 may include a row of vias arranged in the same direction as the width W2. The conductive structure 20 has a first side 20s1 and a second side 20s2 opposite to the first side 20s1. The row of the vias 20v1 is closer to the first side 20s1 than the second side 20s2. The row of the vias 20v2 is closer to the second side 20s2 than the first side 20s1. In other words, the conductive vias 20v1 and 20v2 are disposed adjacent to the opposite sides 20s1 and 20s2, respectively, of the conductive structure 20 (or the component 2).

In some embodiments, the conductive vias 10v1, 10v2, 20v1, and 20v2 may be substantially the same. The conductive structure 20 and conductive vias 20v1 and 20v2 may be made of metal, e.g., Cu, Ti, Au, or the like.

The length L2 of the conductive layer 20a is different from the length L1 of the conductive layer 10a. The length L2 is greater than the length L1. The length L2 of the conductive layer 20a is multiple times greater or smaller than the length L1 of the conductive layer 10a. The length L2 is twice as long as the length L1. The width W1 is equal to the width W2. Therefore, the property (e.g., resistance) of the conductive layer 20a may be twice as large as that of the conductive layer 10a. The component 1 has a property (e.g., resistance) Rtot₁ which may be equal to the resistance of the conductive vias 10v1, the conductive layer 10a, and the conductive vias 10v2 in series. The component 2 has a property (e.g., resistance) Rtot₂ which may be equal to the resistance of the conductive vias 20v1, the conductive layer 20a, and the conductive vias 20v2 in series.

In some embodiments, the dimension of the conductive layer 10a may be a ratio of the length L1 to the width W1. The dimension of the conductive layer 20a may be a ratio of the length L2 to the width W2.

The relationship as shown in FIG. 2 is a first linear relationship associated the property Rtot₁ and the property Rtot₂. Based on the first linear relationship, a property (e.g., resistance) Rv of the conductive vias 10v1 (or 10v2, 20v1, 20v2) can be calculated or determined. When the property Rtot₂ is divided by two, the property 1/2*(Rtot₂) is equal to the resistance of the conductive vias 20v1 and a half of the conductive layer 20a (referring to the numeral 20a′) in series. The property Rv of the conductive vias 10v1 can be calculated by subtracting the property 1/2*(Rtot₂) from the property Rtot₁. The first linear relationship may be expressed by an equation, e.g., Rv=Rtot₁−1/2*(Rtot₂) as illustrated in FIG. 2. The contribution of the conductive vias 10v1 (or 20v1) to the property Rtot₁ (or Rtot₂) can be determined. Furthermore, the property Rc of each of the conductive vias 10v can be calculated by multiplying the number of conductive vias 10v (e.g., three).

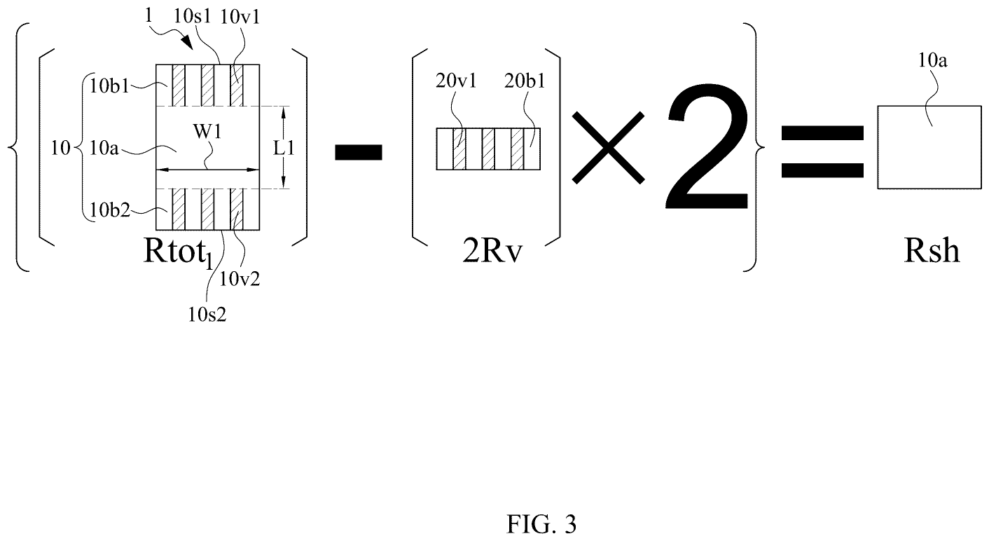

FIG. 3 is a schematic diagram of a relationship between components of the semiconductor device 100, in accordance with some embodiments. The relationship is a second linear relationship associated the property Rtot₁ and the property Rv. Based on the second linear relationship, a property (e.g., resistance) Rsh of the conductive layer 10a can be calculated or determined. When the property Rv is multiplied with two, the property Rsh of the conductive layer 10a can be calculated or determined by subtracting the property 2*Rv from the property Rtot₁. The second linear relationship may be expressed by an equation, e.g., Rsh=Rtot₁−2*(Rv) as illustrated in FIG. 3. The property of the conductive layer 20a may be 2*Rsh when the length L2 is twice as long as the length L1. The contribution of the conductive layer 10a (or 20a) to the property Rtot₁ (or Rtot₂) can be determined. The property Rsh may be a sheet resistance. The property Rsh may be a resistance of the square of the conductive layer 10a. The property Rsh is proportional to the length L1 and the reciprocal of the width W2.

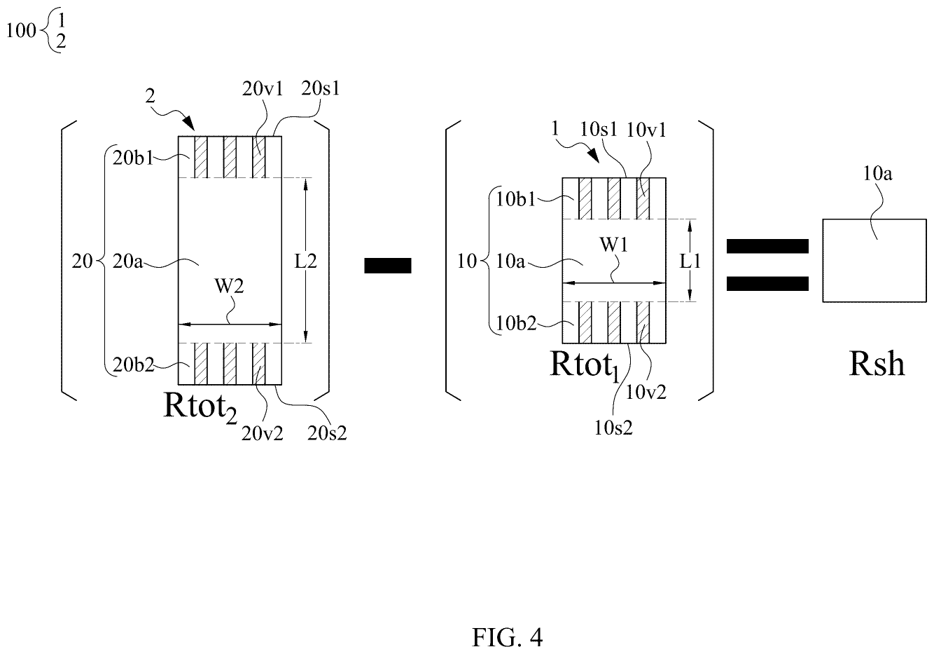

FIG. 4 is a schematic diagram of a relationship between components of the semiconductor device 100, in accordance with some embodiments. The relationship is a third linear relationship associated the property Rtot₁ and the property Rtot₂. Based on the third linear relationship, the property (e.g., resistance) Rsh of the conductive layer 10a can be calculated or determined. The third linear relationship may be expressed by an equation, e.g., Rsh=Rtot₂−Rtot₁. The property of the conductive layer 20a may be 2*Rsh when the length L2 is twice as long as the length L1. The contribution of the conductive layer 10a (or 20a) to the property Rtot₁ (or Rtot₂) can be determined.

The contribution of the conductive vias 10v1 (or 10v2, 20v1, 20v2) and that of the conductive layer 10a (or 10b) to the property Rtot₁ (or Rtot₂) can be decoupled from each other. This is beneficial for determining the contribution of the conductive vias to the property Rtot₁ (or Rtot₂) when variations of the conductive vias occur.

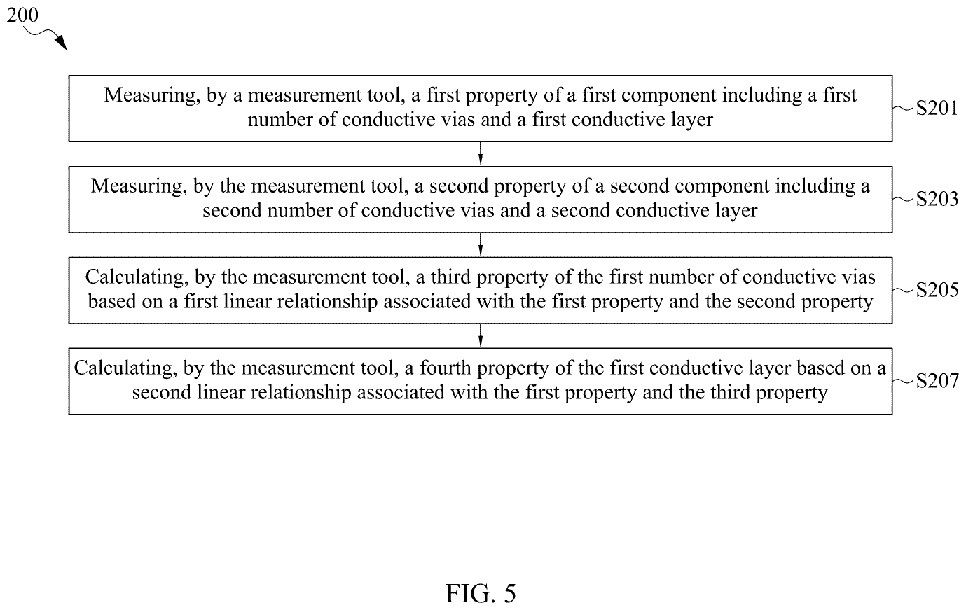

FIG. 5 is a flowchart showing a method 200 of obtaining electrical characteristics of components of a semiconductor device 100, in accordance with some embodiments. The method 200 may be implemented by the semiconductor devices 100 as shown in FIGS. 1-4 and the measurement tool 60. The method 200 includes operations S201, S203, S205, and S207. The sequence of the operations S201, S203, S205, and S207 may be exemplary and will not delimit the present disclosure.

The method 200 begins with operation S201 including measuring, by a measurement tool (e.g., 60), a first property (e.g., Rtot₁) of a first component (e.g., 1) including a first number of conductive vias (e.g., 10v1) and a first conductive layer (e.g., 10a). The measurement includes applying stimulus by a probe apparatus (e.g., 61) of the measurement tool to a semiconductor device (e.g., 100), which includes the first component. The measurement includes detecting electrical signals from the semiconductor device. The measurement includes analyzing the electrical signals to determine the first property.

In operation S203, the method 200 includes measuring, by the measurement tool, a second property (e.g., Rtot₂) of a second component (e.g., 2) including a second number of conductive vias (e.g., 10a) and a second conductive layer (e.g., 20a). The measurement includes applying stimulus by the probe apparatus of the measurement tool to the semiconductor device, which includes the second structure. The measurement includes detecting electrical signals from the semiconductor device. The measurement includes analyzing the electrical signals to determine the second property.

In operation S205, the method 200 includes calculating, by the measurement tool (e.g., 60), a third property (e.g., Rv) of the first conductive vias based on a first linear relationship associated with the first property and the second property. The first linear relationship may be expressed by an equation, e.g., Rv=Rtot₁−1/2*(Rtot₂), as illustrated in FIG. 2.

In operation S207, the method 200 includes calculating, by the measurement tool (e.g., 60), a fourth property (e.g., Rsh) of the first conductive layer based on a second linear relationship associated with the first property and the third property. The second linear relationship may be expressed by an equation, e.g., Rsh=Rtot₁−2*(Rv), as illustrated in FIG. 3.

The contribution of the first and second conductive vias and that of the first and second conductive layer to the property Rtot₁ (or Rtot₂) can be decoupled from each other. This is beneficial for determining the contribution of the conductive vias to the property Rtot₁ (or Rtot₂) when variations of the conductive vias occur.

The method 200 is merely an example, and is not intended to limit the present disclosure beyond what is explicitly recited in the claims. Additional operations can be provided before, during, or after each operation of the method 200, and some operations described can be replaced, eliminated, or reordered for additional embodiments of the method. In some embodiments, the method 200 can include further operations not depicted in FIG. 5. In some embodiments, the method 200 can include one or more operations depicted in FIG. 5.

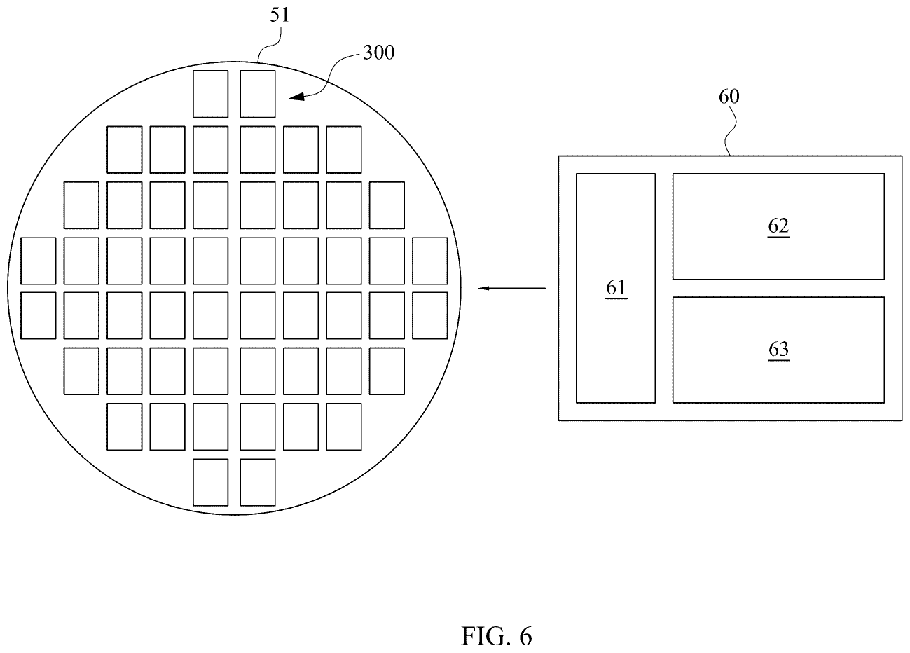

FIG. 6 is a schematic diagram of a substrate 51 and a measurement tool 60, in accordance with some embodiments. The measurement tool 60 of FIG. 6 is identical or similar to the measurement tool 60 of FIG. 1.

The substrate 51 includes a plurality of semiconductor devices 300. The semiconductor devices 300 are distributed across the substrate 51. The semiconductor devices 300 may be separated from each other by a scribe line. The substrate 51 may be subjected to the singulation process to divide the semiconductor devices 300 into different units. The substrate 51 may be a wafer. The semiconductor devices 300 may be dies. The semiconductor devices 300 include integrated circuits. The semiconductor devices 300 may include one or more processing elements and one or more memory elements electrically connected to the processing elements. The processing element(s) and the memory element(s) may be divided from or originate in a monolithic processing unit (e.g., a CPU, a MPU, a GPU, an MCU, an ASIC, or the like). In some embodiments, the processing element may be a CPU chiplet, an MCU chiplet, a GPU chiplet, an ASIC chiplet, or the like. The semiconductor devices 300 may include passive elements, e.g., resistors, capacitors, inductors, or the like.

In some embodiments, the substrate 51 may be a tape and the semiconductor devices 300 may be divided units that are attached to the tape.

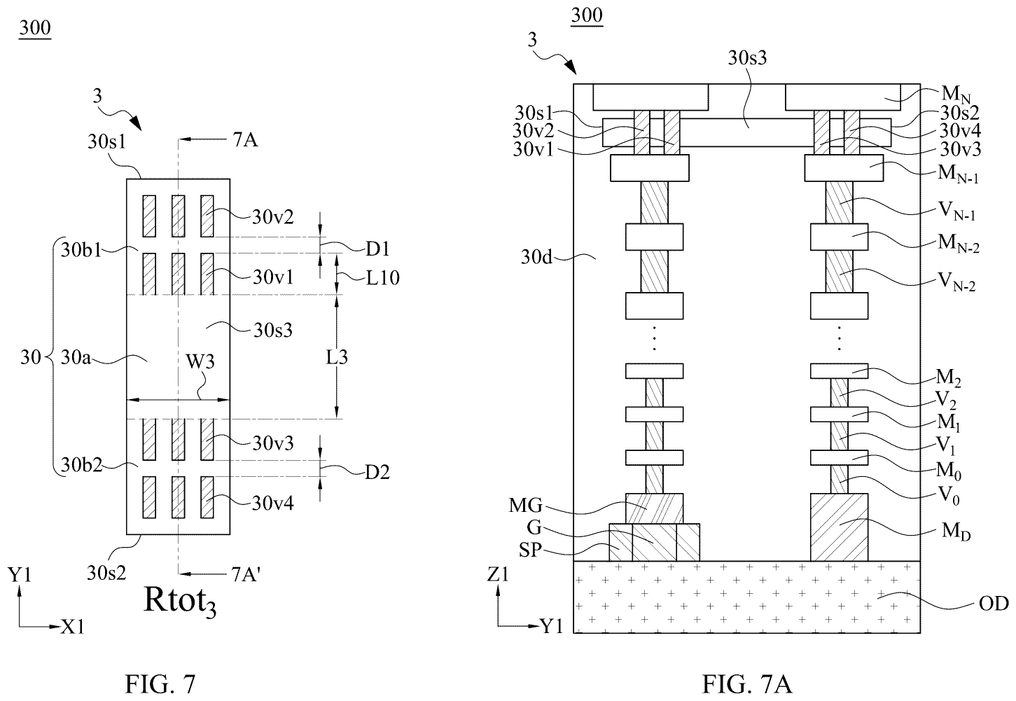

FIG. 7 is a schematic diagram of a top view of a component (e.g., a resistor or resistive device) 3 of a semiconductor device 300, in accordance with some embodiments. The semiconductor device 300 is one of the semiconductor devices 300 of the substrate 50. The semiconductor device 300 of FIG. 7 may be detected, measured, or monitored by the measurement tool 60.

The component 3 includes a conductive structure 30. The conductive structure 30 includes a conductive layer 30a, a via region 30b1, and a via region 30b2. The conductive layer 30a is disposed between the via regions 30b1 and 30b2. The dashed line between the conductive layer 30a and one of the via regions 30b1 and 30b2 is merely used to indicate the locations thereof. There may be no boundary/interface between the conductive layer 30a and one of the via regions 30b1 and 30b2. The via regions 30b1 and 30b2 may be made from a conductive material. The via regions 30b1 and 30b2 may be part of the conductive layer 30a.

The conductive layer 30a has a length L3 and a width W3 perpendicular to the length L3. The length L3 may extend along the direction Y1 and the width W3 may extend along the direction X1, which is perpendicular to the direction Y1. The component 3 includes a plurality of conductive vias 30v1 and 30v2 disposed in the via region 30b1 and a plurality of conductive vias 30v3 and 30v4 disposed in the via region 30b2. The conductive vias 30v1 and 30v2 may each include a row of vias arranged along the direction X1. The conductive vias 30v1 and 30v2 may be referred to as a first array of vias. The conductive vias 30v3 and 30v4 may each include a row of vias arranged along the direction X1. The conductive vias 30v3 and 30v4 may be referred to as a second array of vias. The conductive structure 30 has a first side 30s1 and a second side 30s2 opposite to the first side 30s1. The row of the vias 30v1 is closer to the first side 30s1 than the second side 30s2. The row of vias 30v2 is disposed between the first side 30s1 of the conductive structure 30 and the row of vias 30v1. The row of the vias 30v3 is closer to the second side 30s2 than the first side 30s1. The row of vias 30v4 is disposed between the second side 30s2 of the conductive structure 30 and the row of vias 30v3.

The conductive structure 30 and conductive vias 30v1, 30v2, 30v3, and 30v4 may be made of metal, e.g., Cu, Ti, Au, or the like.

The conductive layer 30a is disposed between the row of vias 30v1 and the row of vias 30v3. The dimension (or the length) L3 of the conductive layer 30a is greater than a dimension L10 of the row of vias 30v1 along the direction Y1. In some embodiments, the conductive vias 30v1, 30v2, 30v3, and 30v4 may be substantially the same. The row of vias 30v2, 30v3, and 30v4 may have substantially the same dimension as the dimension L10 of the row of vias 30v1.

A distance D1 between the row of vias 30v1 and the row of vias 30v2 in the direction Y1 and perpendicular to the first side 30s1 is smaller than the dimension L3 of the conductive layer 30a in the direction Y1. A distance D2 between the row of vias 30v3 and the row of vias 30v4 in the direction Y1 and perpendicular to the second side 30s2 is smaller than the dimension L3 of the conductive layer 30a in the direction Y1. The distance D1 may be substantially the same as the distance D2. The distances D1 and D2 may have a lower limit defined by the via-to-via spacing of the wafer node of the semiconductor device 300.

FIG. 7A is a schematic diagram of a cross-sectional view of the component 3 of the semiconductor device 300, in accordance with some embodiments. The cross-section view of the component 3 may be along the line 7A-7A′ in FIG. 7. The cross-sectional view of FIG. 7A provides more details on the location of the component 3 and its connections with other components in the semiconductor device 300.

The semiconductor device 300 includes an active region OD, a gate G, a spacer SP, a conductive pattern MD, and a conductive pattern MG. The active region OD is disposed below the component 3. The gate G is disposed over the active region OD and surrounded by the spacer SP. There is an insulation layer between the active region OD and the gate G. The gate G is configured to control the channel in the active region OD. The gate G may include a poly gate or a metal gate. The active region OD and the gate G may form an active device, such as a transistor. The conductive pattern MG is disposed over the gate G and electrically connected to the gate G. The conductive pattern MD is disposed over the active region OD and electrically connected to the drain/source of the active region OD. The conductive pattern MD is formed over the active region OD to define electrical connections from the active devices formed in the active region OD to outside circuitry. The conductive pattern MD and MG may each include contacts. The component 3 is disposed over and electrically connected to the active region OD and/or the gate G. The active region OD is disposed below the component 3.

The semiconductor device 300 includes a plurality of back-end-of-line (BEOL) elements, including a plurality of via patterns V₀, V₁, V₂, . . . , V_{N-2}, and V_{N-1} and a plurality of metal patterns M₀, M₁, M₂, . . . , M_{N-2}, M_{N-1}, and MN, wherein N is an integer. The plurality of via patterns V₀, V₁, V₂, . . . , V_{N-2}, and V_{N-1} and the plurality of metal patterns M₀, M₁, M₂, . . . , M_{N-2}, and M_{N-1} are alternately arranged in the direction Z1, which is perpendicular to the direction Y1. The plurality of via patterns V₀, V₁, V₂, . . . , V_{N-2}, and V_{N-1} and the plurality of metal patterns M₀, M₁, M₂, . . . , M_{N-2}, M_{N-1}, and MN may be made of metal, e.g., Cu, Ti, Au, or the like. Therefore, there may be no boundary therebetween. Each of the via patterns V₀, V₁, V₂, . . . , V_{N-2}, and V_{N-1} and the corresponding metal pattern (e.g., M₀ corresponding to V₀) may be formed concurrently. The via pattern V₀ is the lowermost via pattern that directly contacts the conductive patterns MG and MD. The metal pattern M₀ is the lowermost metal pattern that directly contacts the via pattern V₀. The dimension of the via patterns V₀, V₁, V₂, . . . , V_{N-2}, and V_{N-1} and the metal patterns M₀, M₁, M₂, . . . , M_{N-2}, M_{N-1}, and MN may increase as N increases (or the elevation in the Z-direction increases). The metal pattern MN is at an elevation higher than that of the metal pattern M_{N-1} with respect to the active region OD. The metal pattern MN may be connected to an upper metal pattern (not shown), which may be made of aluminum alloy.

The semiconductor device 300 includes a dielectric layer 30d disposed over the active region OD. The dielectric layer 30d may have a single-layer structure or a stacking structure. The conductive patterns MD and MG, the gate G, and the spacer SP are enclosed or surrounded by the dielectric layer 30d. The plurality of via patterns V₀, V₁, V₂, . . . , V_{N-2}, and V_{N-1} and the plurality of metal patterns M₀, M₁, ₂, . . . , M_{N-2}, M_{N-1}, and MN are enclosed or surrounded by the dielectric layer 30d. The conductive structure 30 is enclosed or surrounded by the dielectric layer 30d.

As shown in FIG. 7A, the component 3 is disposed between the plurality of back-end-of-line (BEOL) elements (or the metal patterns) M_{N-1} and MN in the direction Z1. In some embodiments, the metal pattern MN may be the most adjacent metal pattern for the metal pattern M_{N-1} and no metal pattern may be disposed between the metal patterns M_{N-1} and MN. The component 3 is electrically connected to the metal patterns M_{N-1} and MN. A first portion of the metal pattern M_{N-1} contacts the conductive vias 30v1 and 30v2 and a second portion of the metal pattern M_{N-1} contacts the conductive vias 30v3 and 30v4. The first and second portions of the metal pattern M_{N-1} are separated by the dielectric layer 30d. A first portion of the metal pattern MN contacts the conductive vias 30v1 and 30v2 and a second portion of the metal pattern MN contacts the conductive vias 30v3 and 30v4. The first and second portions of the metal pattern M_{N} are separated by the dielectric layer 30d. The conductive vias 30v1 and 30v2 are connected in parallel. The conductive vias 30v3 and 30v4 are connected in parallel.

The conductive structure 30 has a first surface 30s3 connected between the first side 30s1 and the second side 30s2. The conductive vias 30v1, 30v2, 30v3, and/or 30v4 extend through the conductive structure 30 in a direction (e.g., Z1) substantially perpendicular to the surface 30s3.

Referring back to FIG. 7, the component 3 has a property (e.g., resistance) Rtot3 which may be equal to the resistance of the conductive vias 30v1 and 30v2, the conductive layer 30a, and the conductive vias 30v3 and 30v4 in series. The component 3 has a plurality of rows of conductive vias 30v1 and 30v2 connected in parallel at the first side 30s1 and a plurality of rows of conductive vias 30v3 and 30v4 connected in parallel at the second side 30s2. The equivalent resistance of the conductive vias 30v1, 30v2, 30v3, and 30v4 is relatively small compared to that of a component including one row at each side. The contribution of the conductive vias 30v1, 30v2, 30v3, and 30v4 to the property Rtot3 is reduced. As such, the variation of the property (e.g., the resistance) of the conductive vias which would be induced by the manufacturing process may be reduced and thus the property Rtot3 of the component 3 is insensitive to the variation of the resistance (e.g., Rc) of the conductive vias 30v1, 30v2, 30v3, and 30v4. Furthermore, since the contribution of the resistance Rc to the property Rtot3 of the component 3 is decreased, the design range of the dimension (e.g., the ratio of L3 over W3) of the conductive layer 30a can be increased, which provides more resistance options for the circuit design.

The semiconductor device 300 may include a bandgap reference circuit having two resistors intended to be matched with each other. The component 3 with the Rc-insensitive property Rtot3 can improve the resistance matching in said bandgap reference circuit. The component 3 with the Rc-insensitive property Rtot3 can be included in a thermal sensor (or a thermistor) of the semiconductor device 300.

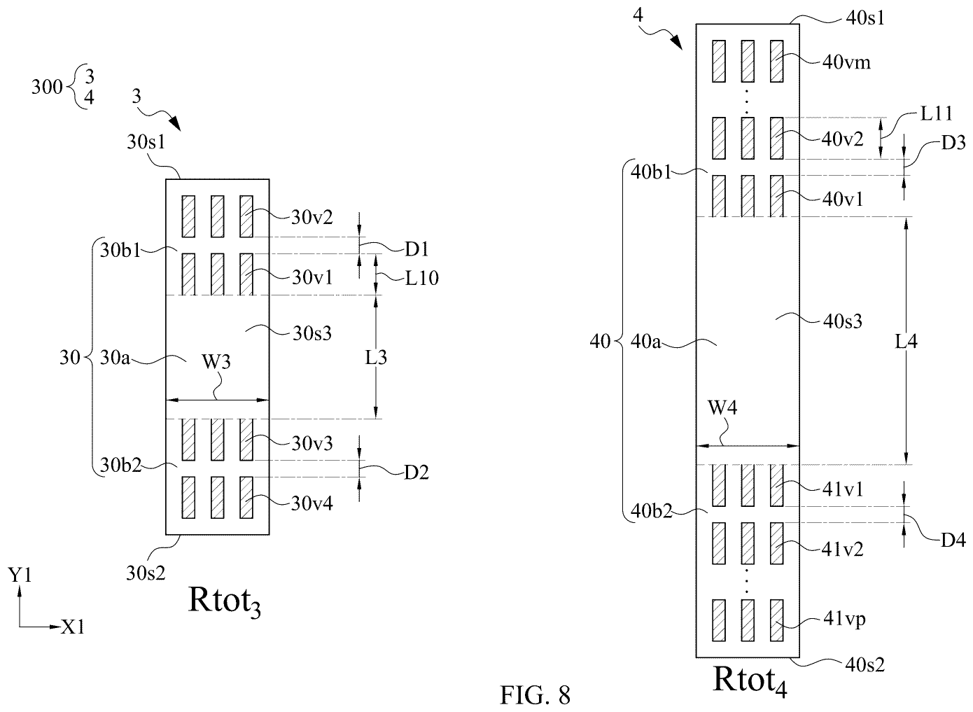

FIG. 8 is a schematic diagram of a top view of components of a semiconductor device 300, in accordance with some embodiments. The semiconductor device 300 of FIG. 8 includes the component 3 as illustrated in FIG. 7. The semiconductor device 300 of FIG. 8 further includes a component 4. The components 3 and 4 may be disposed in an array of components (or resistors). In some embodiments, the components 3 and 4 may be disposed in different arrays of components (or resistors). The component 4 may be disposed adjacent to the component 3. The component 4 may be distant from the component 3. The components 3 and 4 may be separated by the dielectric layer 30d of FIG. 7A. The components 3 and 4 may be disposed at the same elevation with respect to the active region OD of FIG. 7A. The component 4 may be disposed between the plurality of back-end-of-line (BEOL) elements (or the metal patterns) MN-1 and MN in the direction Z1 of FIG. 7A.

The component 4 includes a conductive structure 40. The conductive structure 40 includes a conductive layer 40a, a via region 40b1, and a via region 40b2. The conductive layer 40a is disposed between the via regions 40b1 and 40b2. The dashed line between the conductive layer 40a and one of the via regions 40b1 and 40b2 is merely used to indicate the locations thereof. There may be no boundary/interface between the conductive layer 40a and one of the via regions 40b1 and 40b2. The via regions 40b1 and 40b2 may be made from a conductive material. The via regions 40b1 and 40b2 may be part of the conductive layer 40a.

The conductive layer 40a has a dimension (or length) L4 and a dimension (or width) W4 perpendicular to the length L4. The length L4 may extend along the direction Y1 and the width W4 may extend along the direction X1, which is perpendicular to the direction Y1. The length L4 of the component 4 may be different from the length L3 of the component 3. The length L4 of the conductive layer 40a is twice as long as the length L3 of the conductive layer 30a. In some embodiments, the dimension of the conductive layer 30a may be a ratio of the length L3 to the width W3. The dimension of the conductive layer 40a may be a ratio of the length L4 to the width W4.

The component 4 includes a plurality of rows of conductive vias 40v1, 40v2, . . . , 40vm disposed in the via region 40b1 and a plurality of rows of conductive vias 41v1, 41v2, . . . , 41vp disposed in the via region 40b2, wherein “m” and “p” may be positive integers. In other words, an M row of conductive vias may be disposed between the first side 40s1 and the row of conductive vias 40v1, wherein M is an integer more than 2. The rows of conductive vias 40v1, 40v2, . . . , 40vm may be referred to as a first array of vias. The plurality of rows of conductive vias 41v1, 41v2, . . . , 41vp may be referred to as a second array of vias. The conductive structure 40 has a first side 40s1 and a second side 40s2 opposite to the first side 40s1. The first array of the vias 40v1, 40v2, . . . , 40vm is closer to the first side 40s1 than the second side 40s2. The second array of the vias 41v1, 41v2, . . . , 41vp is closer to the second side 40s2 than the first side 40s1.

The conductive structure 40, the first array of the vias 40v1, 40v2, . . . , 40vm, and the second array of the vias 41v1, 41v2, . . . , 41vp may be made of metal, e.g., Cu, Ti, Au, or the like.

The conductive layer 40a is disposed between the first array of vias 40v1, 40v2, . . . , 40vm and the second array of vias 41v1, 41v2, . . . , 41vp. The dimension (or the length) L4 of the conductive layer 40a is greater than a dimension L11 of the row of vias 40v2 along the direction Y1. In some embodiments, the conductive vias 40v1, 40v2, . . . , 40vm and 41v1, 41v2, 41vp may be substantially the same. The conductive vias 41v1, 41v2, . . . , 41vp may have substantially the same dimension as the dimension L11.

A distance D3 between the first array of vias 40v1, 40v2, . . . , 40vm in the direction Y1 and perpendicular to the first side 40s1 is smaller than the dimension L4 of the conductive layer 30a. A distance D4 between the second array of vias 41v1, 41v2, . . . , 41vp in the direction Y1 and perpendicular to the second side 40s2 is smaller than the dimension L4 of the conductive layer 40a. The distance D3 may be substantially the same as the distance D4. The distances D3 and D4 may have a lower limit defined by the via-to-via spacing of the wafer node of the semiconductor device 300.

The component 4 has a property (e.g., resistance) Rtot4 which may be equal to the resistance of the first array of conductive vias 40v1, 40v2, . . . ,40vm, the conductive layer 40a, and the second array of conductive vias 41v1, 41v2, . . . ,41vp in series. The array arrangement of the conductive vias decreases the equivalent resistance thereof. The contribution of the array of conductive vias 40v1, 40v2, . . . , 40vm (or 41v1, 41v2, . . . , 41vp) to the property Rtot₄ is reduced. In other words, a contribution of the resistance of the array of conductive vias to the property (or resistance) of the component 4 is decreased as a number of rows of vias 40v1, 40v2, . . . ,40vm (or 41v1, 41v2, . . . ,41vp) in the rows of conductive vias 40v1, 40v2, . . . ,40vm (or 41v1, 41v2, . . . ,41vp) is increased. As such, the variation of the property (e.g., the resistance) of the conductive vias which would be induced by the manufacturing process may be reduced and thus the property Rtot₄ of the component 4 can be more stable. The components 3 and 4 are insensitive to the variation of the resistance (e.g., Rc) of the conductive vias. The property Rtot₃ is different from the property Rtot₄. It is provided that the semiconductor device 300 has multiple resistors with Rc-insensitive resistances.

In some embodiments, the method 200 of FIG. 5 may be implemented by the semiconductor devices 300 as shown in FIGS. 6, 7, 7A, and 8 and the measurement tool 60.

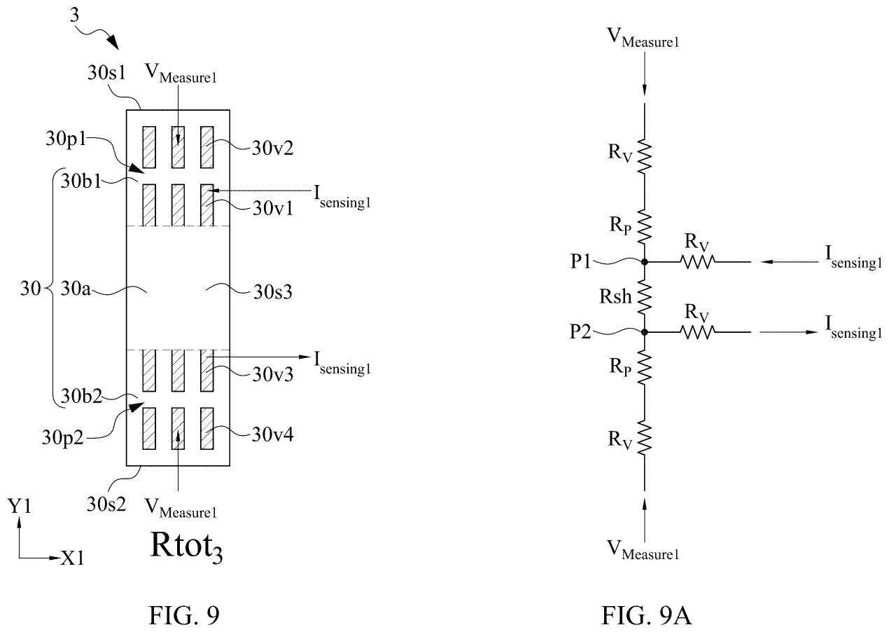

FIG. 9 is a schematic diagram of the measurement of the component 3 of the semiconductor device 300, in accordance with some embodiments. FIG. 9 provides an additional measurement for obtaining the property of the component 3.

As shown in FIG. 9, a first current signal I_{sensing1} is input to the row of conductive vias 30v1 and output from the row of conductive vias 30v3 to determine the property of the conductive layer. A first voltage signal Vₘₑₐₛᵤᵣₑ₁ across the conductive layer 30a is measured with the row of conductive vias 30v2 and the row of conductive vias 30v4. The setting of the first current signal I_{sensing1} and the first voltage signal Vₘₑₐₛᵤᵣₑ₁ can be referred to as the Kelvin sense setting. The closest pair of the rows of conductive vias 30v1 and 30v3 are the terminals for inputting and outputting the first current signal I_{sensing1}. The other pair of the rows of conductive vias 30v2 and 30v4 are the terminals for measuring the first voltage signal Vₘₑₐₛᵤᵣₑ₁ across the conductive layer 30a.

FIG. 9A is a circuit diagram equivalent to the measurement of the component 3 of the semiconductor device 300 in FIG. 9.

As shown in FIG. 9A, the conductive vias 30v1, 30v2, 30v3, and 30v4 are equivalent to the element Rv, and the conductive layer 30a is equivalent to the element Rsh. The element Rsh has points P1 and P2 that are separately connected to the elements Rv. There is a parasitic resistor Rp that represents a region 30p1 between the conductive vias 30v1 and a region 30p2 between the conductive vias 30v2 and 30v3 and 30v4. Based on the first current signal I_{sensing1} and the first voltage signal Vₘₑₐₛᵤᵣₑ₁, the property (e.g., the resistance) Rsh of the conductive layer 30a can be obtained, e.g., with an equation of Rsh=Vₘₑₐₛᵤᵣₑ₁/I_{sensing1}. The component 3 includes at least two rows of conductive vias at opposite sides 30s1 and 30s2. The first current signal I_{sensing1} and the first voltage signal Vₘₑₐₛᵤᵣₑ₁ can be applied at different terminals (i.e., the Kelvin sense setting). Since the first current signal I_{sensing1} interacts with the first voltage signal Vₘₑₐₛᵤᵣₑ₁ at the points P1 and P2 of the conductive layer 30a, the property Rsh of the conductive layer 30a can be directly obtained. The contribution of the property Rsh to the property Rtot₃ of the component 3 can be determined.

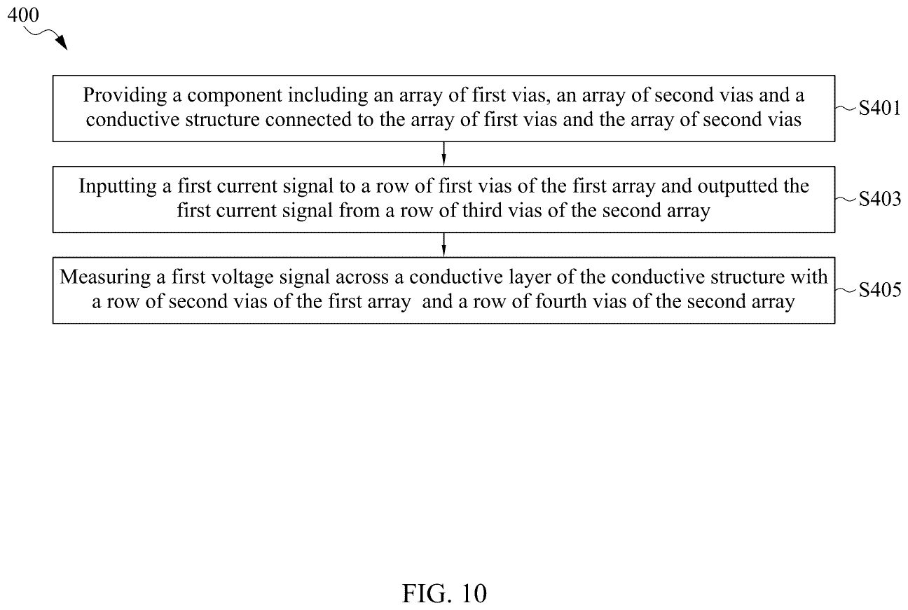

FIG. 10 is a flowchart showing a method 400 of obtaining electrical characteristics of components of the semiconductor device 300, in accordance with some embodiments. The method 400 may be implemented by the semiconductor devices 300 as shown in FIGS. 6, 7, 7A, and 8 and the measurement tool 60. The method 400 includes operations S401, S403, and S405. The sequence of the operations S401, S403, and S405 may be exemplary and will not delimit the present disclosure.

The method 400 begins with operation S401 including providing a component (or a resistor, a resistive device, e.g., the component 3 or 4) including an array of first vias (e.g., 30v1, 30v2, or 40v1, 40v2, . . . , 40vm), an array of second vias (e.g., 30v3, 30v4, or 41v1, 41v2, . . . , 41vp) and a conductive structure (e.g., 30 or 40) connected to the array of first vias and the array of second vias.

In operation S403, the method 400 includes inputting a first current signal (e.g., I_{sensing1}) to a row of first vias (e.g., 30v1, or 40v1) of the first array and outputting the current signal from a row of third vias (e.g., 30v3, or 41v2) of the second array. The first current signal may be input by the probe apparatus of the measurement tool.

In operation S405, the method 400 includes measuring a first voltage signal Vₘₑₐₛᵤᵣₑ₁ across a conductive layer (e.g., 30a or 40a) of the conductive structure with a row of second vias (e.g., 30v2, or 40v2) of the first array and a row of fourth vias (e.g., 30v4, or 41v2) of the second array. The electrical characteristics (e.g., Rsh) of the component can be obtained based on the first voltage signal Vₘₑₐₛᵤᵣₑ₁ and the first current signal I_{sensing1}.

The method 400 is merely an example, and is not intended to limit the present disclosure beyond what is explicitly recited in the claims. Additional operations can be provided before, during, or after each operation of the method 400, and some operations described can be replaced, eliminated, or reordered for additional embodiments of the method. In some embodiments, the method 400 can include further operations not depicted in FIG. 10. In some embodiments, the method 400 can include one or more operations depicted in FIG. 10.

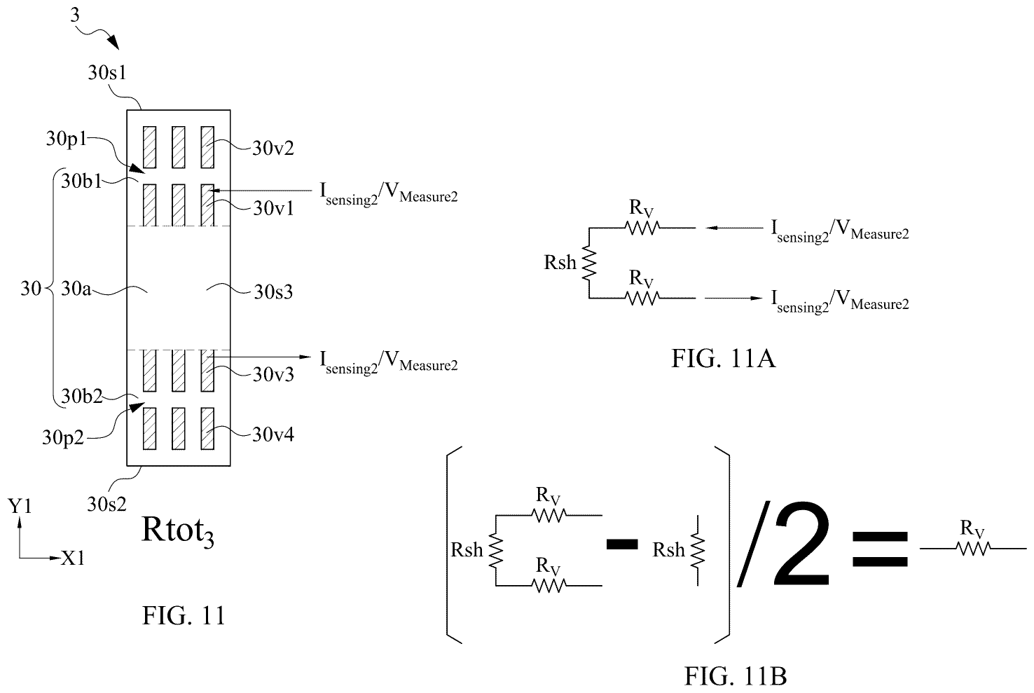

FIG. 11 is a schematic diagram of the measurement of a component of a semiconductor device, in accordance with some embodiments. FIG. 11 provides an additional measurement for obtaining the property of the component 3.

As shown in FIG. 11, a second current signal I_{sensing2} is input to the row of vias 30v1 and output from the row of conductive vias 30v3 to determine an overall resistance of the conductive layer 30a, the row of the conductive vias 30v1, and the row of conductive vias 30v3. A second voltage signal Vₘₑₐₛᵤᵣₑₘₑₙₜ₂ across the conductive layer 30a, the row of the conductive vias 30v1, and the row of the conductive vias 30v3 is measured with the row of conductive vias 30v1 and the row of conductive vias 30v3.

FIG. 11A is a circuit diagram equivalent to the measurement of the component 3 of the semiconductor device 300 in FIG. 11.

As shown in FIG. 11A, the conductive vias 30v1 and 30v3 are equivalent to the element Rv and the conductive layer 30a is equivalent to the element Rsh. Based on the second current signal I_{sensing2} and the second voltage signal Vₘₑₐₛᵤᵣₑ₂, the resistance Rsh and 2*Rv of the conductive layer 30a, the row of the conductive vias 30v1, and the row of conductive vias 30v3 in series can be obtained.

FIG. 11B is a schematic diagram of a relationship between components of the semiconductor device 300, in accordance with some embodiments. The relationship as shown in FIG. 11B is a fourth linear relationship associated the property (e.g., resistance) Rsh and 2*Rv. Based on the fourth linear relationship, the property (e.g., resistance) Rv of the conductive vias 30v1 (or 30v2, 30v3, 30v4) can be calculated or determined. The fourth linear relationship may be expressed by an equation, e.g., Rv=1/2*(Rsh+2*Rv)−Rsh). The contribution of the property Rv to the property Rtot₃ of the component 3 can be determined. The contribution of the conductive vias and that of the conductive layer to the property Rtot₃ can be decoupled from each other. This is beneficial for determining the contribution of the conductive vias to the property Rtot₃ when variations of the conductive vias occur.

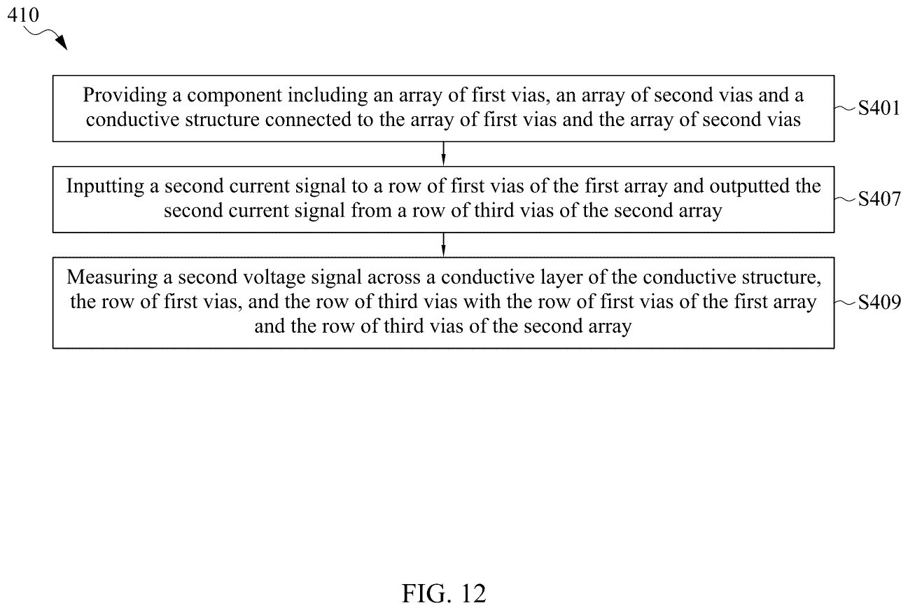

FIG. 12 is a flowchart showing a method 410 of obtaining electrical characteristics of components of a semiconductor device, in accordance with some embodiments. The method 410 may be implemented by the semiconductor devices 300 as shown in FIGS. 6, 7, 7A, and 8 and the measurement tool 60. The method 410 includes operations S401, S407, and S409. The sequence of the operations S401, S403, and S405 may be exemplary and will not delimit the present disclosure. The operation S401 is the same as that in the method 400.

In operation S407, the method 410 includes inputting a second current signal (e.g., I_{sensing2}) to a row of first vias (e.g., 30v1, or 40v1) of the first array and outputting the second current signal from a row of third vias (e.g., 30v3, or 41v2) of the second array. The second current signal may be input by the probe apparatus of the measurement tool.

In operation S409, the method 410 includes measuring a second voltage signal Vₘₑₐₛᵤᵣₑ₂ across a conductive layer (e.g., 30a or 40a) of the conductive structure, the row of first vias, and the row of third vias with the row of first vias of the first array and the row of third vias of the second array. The electrical characteristics (e.g., Rsh+2*Rv) of the component can be obtained based on the second voltage signal Vₘₑₐₛᵤᵣₑ₂ and the second current signal I_{sensing2}.

The method 410 is merely an example, and is not intended to limit the present disclosure beyond what is explicitly recited in the claims. Additional operations can be provided before, during, or after each operation of the method 410, and some operations described can be replaced, eliminated, or reordered for additional embodiments of the method. In some embodiments, the method 410 can include further operations not depicted in FIG. 12. In some embodiments, the method 410 can include one or more operations depicted in FIG. 12.

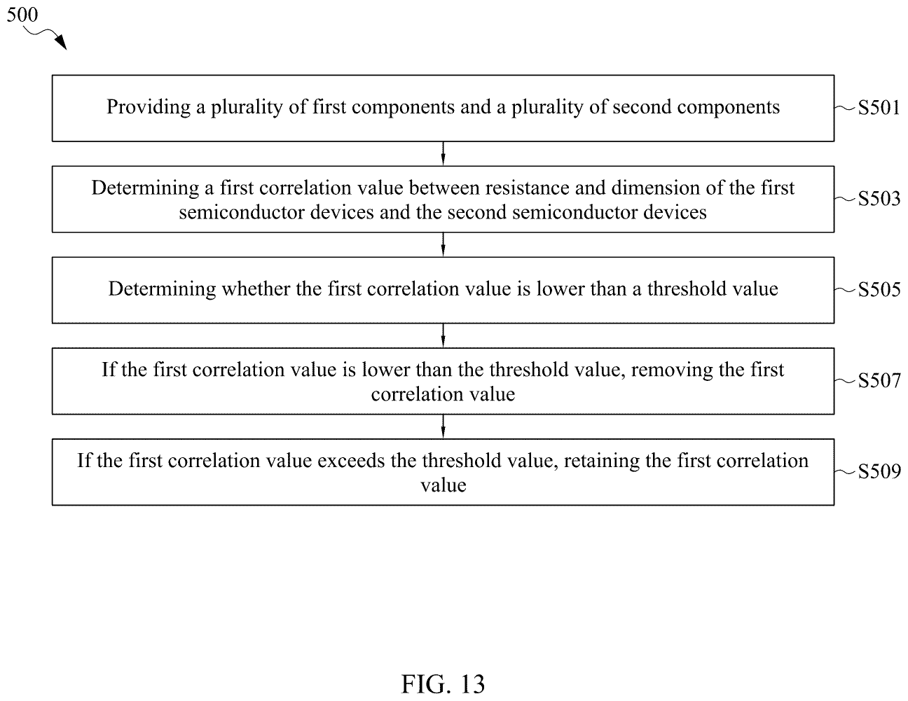

FIG. 13 is a flowchart showing a testing method (or a method) 500, in accordance with some embodiments. The testing method 500 may be implemented by the semiconductor devices 100 as shown in FIGS. 1-4 and the semiconductor devices 300 as shown in FIGS. 6, 7, 7A, and 8 and the measurement tool 60. The method 500 includes operations S501, S503, S505, S507, and S509. The sequence of the operations S501, S503, S505, S507, and S509 may be exemplary and will not delimit the present disclosure.

The method 500 begins with operation S501 including providing a plurality of first components (or first resistors, first resistive devices) and a plurality of second components (or second resistors, first resistive devices). The first components (or the second components) may be included in a semiconductor device (e.g., 100, 300) of a substrate (e.g., 50, 51). The first components (or the second components) are distributed across the semiconductor device. In some embodiments, each of the first components (or the second components) may be distributed in different semiconductor devices (or dies) (e.g., 100, 300) across a substrate (e.g., 50, 51). Each of the first components (or the second components) may be arranged at the corresponding region in the semiconductor devices.

In operation 503, the method 500 includes determining a first correlation value between the resistance and dimensions of the first components and the second components. The first correlation value may be a correlation coefficient. The dimension may be a length (e.g., L1, L2, L3, L4) of a conductive layer (e.g., 10a, 20a, 30a, 40a) of the first components and the second components. The dimension may be a ratio of a length (e.g., L1, L2, L3, L4) to a width (e.g., W1, W2, W3, W4) of a conductive layer (e.g., 10a, 20a, 30a, 40a) of the first components and the second components. The determination of the first correlation value may include measuring the resistance of the first components and the second components. The resistance of the first components and the second components may be obtained based on the method 200, 400, or 410. The determination of the first correlation value is referred to as the resistance-to-resistance correlation. The determination of the first correlation value may include calculating the variance of the resistance and the variance of the dimension, and the correlation coefficient by the means of, e.g., Pearson's product-moment correlation.

In some embodiments, a correlation value between resistance and location of the first components and the second components may be determined. The determination of said correlation value may include calculating the variance of the resistance and the variance of the location, and the correlation coefficient by the means of, e.g., Pearson's product-moment correlation. The location means where the first components and the second components are located in a semiconductor device (e.g., 100 or 300) or in specific semiconductor devices.

In operation 505, the method 500 includes determining whether the first correlation value is lower than a threshold value. The threshold value may be predetermined. The threshold value may be 0.7, 0.75, 0.8, 0.85, 0.9 or more. When the first correlation value exceeds the threshold value, the correlation between the resistance and dimensions (or locations) of the first components and the second components will be considered acceptable.

In operation 507, the method 500 includes, if the first correlation value is lower than the threshold value (e.g., 0.85), removing the first correlation value. The removal of the first correlation value may include discarding the data associated with the first components and the second components.

In operation 509, the method 500 includes, if the first correlation value exceeds the threshold value, retaining the first correlation value. The retention of the first correlation value may include keeping the data associated with the first components and the second components.

The method may include determining which types of components are more reliable. In some embodiments, these types of components may have an Rc-insensitive resistance. These types of components may have a plurality of conductive vias that contributes less in the resistance of the component.

The method 500 is merely an example, and is not intended to limit the present disclosure beyond what is explicitly recited in the claims. Additional operations can be provided before, during, or after each operation of the method 500, and some operations described can be replaced, eliminated, or reordered for additional embodiments of the method. In some embodiments, the method 500 can include further operations not depicted in FIG. 13. In some embodiments, the method 500 can include one or more operations depicted in FIG. 13.

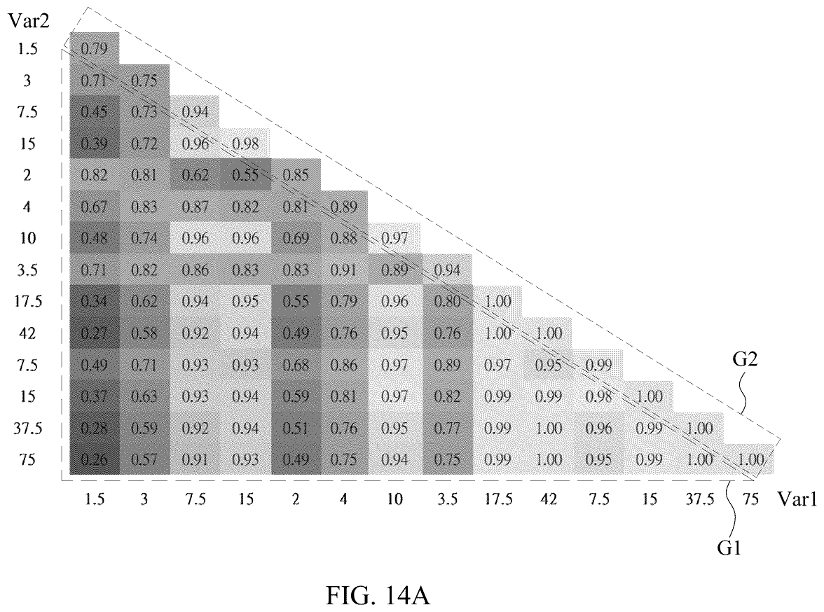

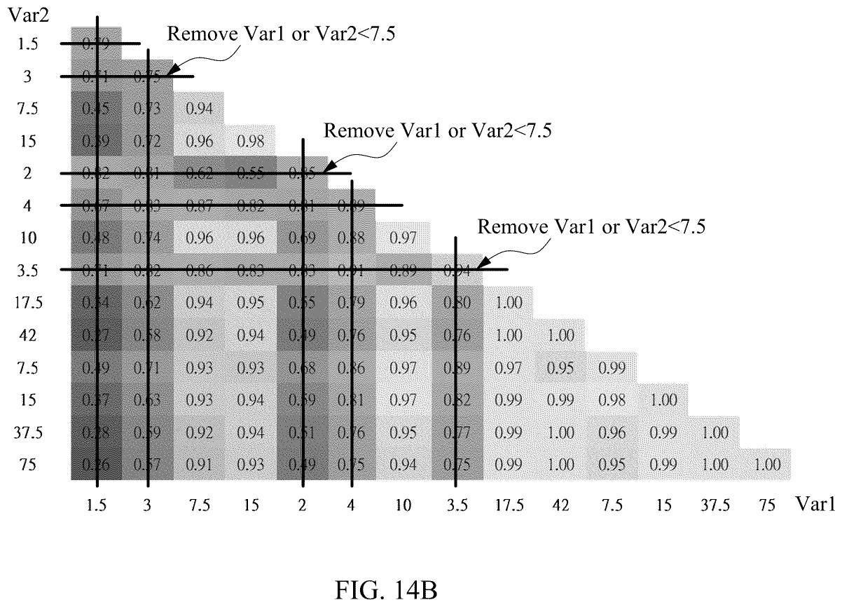

FIG. 14A is a plot of correlation values between a first variable Var1 and a second variable Var2, in accordance with some embodiments. FIG. 14A illustrates further details of the method 500.

Each number of first variable Var1 may correspond to one type of component (or resistor). Each number of second variable Var2 may correspond to one type of component (or resistor). The components may be similar to the component 1, 2, 3, or 4. That is, the components may each include a conductive structure having a first plurality of conductive vias, a second plurality of conductive vias, and a conductive layer disposed therebetween. The first variable Var1 may be the multiplication of a resistance of square (L/W) of the conductive layer, the number of conductive vias, and a constant. The first variable Var1 is different as the length L/width W of the conductive layer, or the number of conductive vias is varied. The second variable Var2 may be the multiplication of a resistance of square (L/W) of the conductive layer, the number of conductive vias, and a constant. The second variable Var2 is different as the length L/width W of the conductive layer, or the number of conductive vias is varied. That is, when the value of the first variable Var1 is different, the dimension of the corresponding component will be different. In some embodiments, the value “75” of the first variable Var1 indicates that the corresponding component has a dimension larger than that of the value “7.5” of the first variable Var2.

Each of the correlation values is determined by operation S503 of the method 500. As shown in FIG. 14A, the correlation value of the value “7.5” of the first variable Var1 and the value “42” of the second variable Var2 is 0.92.

The plot of FIG. 14A may be categorized into two groups, G1 and G2. The group G1 includes the correlation values in which the first variable Var1 and the second variable Var2 are the same. The dimensions of the components of the first variable Var1 and the second variable Var2 may be substantially identical and adjacent to each other, and thus may be referred to as a mismatch pair. In some cases, the mismatch pair may be used to monitor the variations of the conductive vias of the component. The number of testing samples may be relatively small.

The group G2 includes the correlation values when the values of the first variable Var1 and the second variable Var2 are different. The dimensions of the components of the first variable Var1 and the second variable Var2 are different. In the present disclosure, the group G2 provides the correlation values between the components (or resistors) with different dimensions. The group G2 provides more testing samples for resistance-to-resistance correlation, e.g., 20 times larger in number than the group G1, and can capture failures in ppm level.

FIG. 14B illustrates determining the retention and/or removal of correlation values, in accordance with some embodiments.

As shown in FIG. 14B, the correlation values that are lower than a threshold value of, e.g., 0.85, are removed, by operations S505 and S507 of the method 500. In some embodiments, the data associated with the removed threshold values are discarded. It is observed that data associated with the value of the first variable Var1 and the second variable Var2 lower than 7.5 are removed. The correlation values that are higher than a threshold value of, e.g., 0.85, are retained, by operations S505 and S509 of the method 500. The retention of the correlation values identify the types of components which are more reliable. In some embodiments, these types of components may have an Rc-insensitive resistance. These types of components may have a plurality of conductive vias that contributes less in the resistance of the component.

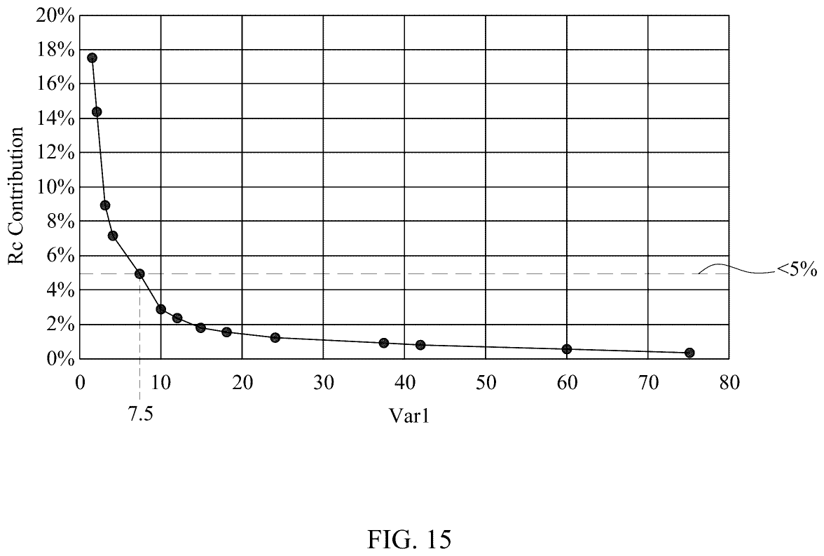

FIG. 15 is a plot of a variable (e.g., the first variable Var1) versus a contribution of the resistance Rc of conductive vias of a component (e.g., 10, 20, 30, 40), in accordance with some embodiments. When the first variable Var1 is equal to or exceeds a number (e.g., 7.5), the contribution of the conductive vias to the property (e.g., Rtot1, Rtot2, Rtot3, Rtot4) of the component is less than 5%, which is an acceptable level. The analysis of the plot of FIG. 15 echoes the analysis of the plot of FIGS. 14A and 14B. That is, when the variable Var1 is equal to or exceeds 7.5, the contribution of the conductive vias to the property is insignificant and the correlation values can exceed the threshold value of, e.g., 0.85.

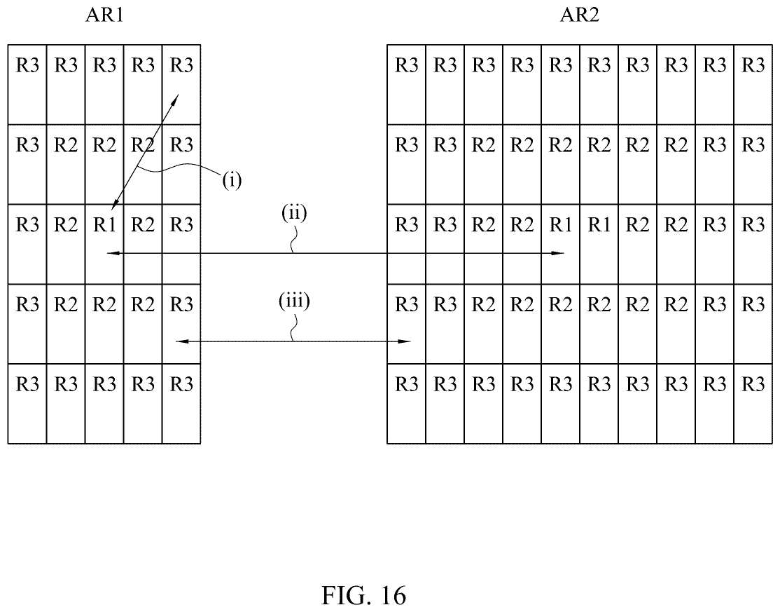

FIG. 16 is a schematic diagram of arrays AR1 and AR2 of a substrate (e.g., the substrate 50 or 51), in accordance with some embodiments.

The arrays AR1 and AR2 may be included in a semiconductor device (or die) (e.g., 100 or 300) of the substrate (e.g., the substrate 50 or 51). In some embodiments, the arrays AR1 and AR2 may be included in different semiconductor devices. In some embodiments, the arrays AR1 and AR2 may include components 1, 2, 3, and/or 4. The array AR1 (or AR2) may include the components 4 and 4. The array AR1 may include the component 3 and the array AR2 may include the component 4.

The array AR1 includes a resistor R1, a plurality of resistors R2, and a plurality of resistors R3. The resistor R1 is surrounded by the resistors R2. The resistors R2 are surrounded by the resistors R3. The resistors R3 may define an edge of the array AR1. In some embodiments, the array AR1 may include additional resistors surrounding the resistor R3. The resistors R1, R2, and R3 may be similar to the components 1, 2, 3, and 4. The resistors R1, R2, and R3 may have different dimensions (e.g., resistances of square). The correlation inside array (i) can be determined. In some embodiments, the correlation between the resistance and the dimension of the resistors R1, R2, and R3 can be determined by the method 500. The correlation (i) between the resistors R1 and R3 can be used to check the density gradient effect (DGE) within the array AR1.

The array AR2 includes a plurality of resistors R1, a plurality of resistors R2, and a plurality of resistors R3. The array AR2 may be larger than the array AR1. In some embodiments, the number of resistors R1 of the array AR2 is greater than that of the array AR1. The number of resistors R2 of the array AR2 is greater than that of the array AR1. The number of resistors R3 of the array AR2 is greater than that of the array AR1.

The correlation across arrays (ii) can be determined. In some embodiments, the correlation between the resistance and the dimension of the resistor R1 of the array AR1 and the corresponding type of the resistor (i.e., R1) of the array AR2 can be determined by the method 500. The correlation (ii) can be used to check the DGE of the same resistor between different-size arrays.

The correlation across the arrays of edge resistors (iii) can be determined. In some embodiments, the correlation between the resistance and the dimension of the resistor R3 of the array AR1 and the corresponding type of the resistor (i.e., R3) of the array AR2 can be determined by the method 500. The correlation (iii) can be used to check the array abutment DGE.

Referring back to FIG. 13, the first components and the second components may be the resistors R1, R2, R3 of the arrays AR1 and AR2. In some embodiments, a first set of the first components may be the resistor R1 of the array ARI and a second set of the second components may be the resistors R2 of the array AR1. In some embodiments, a third set of the first components is the resistor R1 in the array AR1 of the semiconductor device and a fourth set of the second components is the resistor R1 in the array AR2 of the semiconductor device.

According to other embodiments, a resistive device is provided. The resistive device includes a conductive structure, a row of first vias, and a row of second vias. The conductive structure has a first side and a second side opposite to the first side, and a first surface connected between the first side and the second side. The row of first vias extends through the conductive structure in a first direction substantially perpendicular to the first surface. The row of first vias is closer to the first side than the second side. The row of second vias extends through the conductive structure in the first direction. The row of second vias is disposed between the first side of the conductive structure and the row of first vias.

According to other embodiments, a semiconductor device is provided. The semiconductor device includes a first resistor. The first resistor includes a first conductive structure, a first array of vias, a second conductive structure, and a second array of vias. The first conductive structure has a first side and a second side opposite to the first side. The first array of vias is disposed closer to the first side than the second side. The second conductive structure has a third side and a fourth side opposite to the third side. The second array of vias is disposed closer to the third side than the fourth side. The first conductive structure of the first resistor comprises a first conductive layer and the second conductive structure of the second resistor comprises a second conductive layer having a dimension different from that of the first conductive layer.

According to other embodiments, a method of obtaining an electrical characteristic of a component of a semiconductor device includes measuring, by a measurement tool, a first property of a first component including a number of first conductive vias and a first conductive layer; measuring, by the measurement tool, a second property of a second component including a number of second conductive vias and a second conductive layer; and calculating, by the measurement tool, a third property of the first conductive vias based on a first linear relationship associated with the first property and the second property, wherein a dimension of the second conductive layer is different from that of the first conductive layer and a dimension of the first conductive vias is substantially identical to that of the second conductive vias.

According to other embodiments, a testing method includes providing a plurality of first components and a plurality of second components; determining a first correlation value between the resistance and dimensions of the first components and the second components; determining whether the first correlation value is lower than a threshold value; and if the first correlation value is lower than the threshold value, removing the first correlation value.

The methods and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A resistive device, comprising:
a conductive structure having a first side and a second side opposite to the first side, and a first surface connected between the first side and the second side;
a row of first vias extending through the conductive structure in a first direction substantially perpendicular to the first surface, wherein the row of first vias is closer to the first side than the second side; and
a row of second vias extending through the conductive structure in the first direction, wherein the row of second vias is disposed between the first side of the conductive structure and the row of first vias.

2. The resistive device of claim 1, wherein the resistive device is disposed between a plurality of back-end-of-line (BEOL) elements in the first direction.

3. The resistive device of claim 1, further comprising:
a row of third vias extending through the conductive structure in the first direction, wherein the row of third vias is closer to the second side than the first side; and
a row of fourth vias extending through the conductive structure in the first direction, wherein the row of fourth vias is disposed between the second side of the conductive structure and the row of third vias.

4. The resistive device of claim 3, wherein the conductive structure comprises a conductive layer disposed between the row of first vias and the row of third vias, wherein the conductive layer has a dimension greater than that of the row of first vias.

5. The resistive device of claim 4, wherein a distance between the row of first vias and the row of second vias in a second direction perpendicular to the first side is smaller than a dimension of the conductive layer in the second direction.

6. The resistive device of claim 4, further comprising an M row of vias disposed between the first side and the row of second vias, wherein M is an integer more than 2.

7. The resistive device of claim 4, wherein a first current signal is input to the row of first vias and output from the row of third vias to determine a resistance of the conductive layer.

8. The resistive device of claim 7, wherein a first voltage signal across the conductive layer is measured with the row of second vias and the row of fourth vias.

9. The resistive device of claim 4, wherein a second current signal is input to the row of first vias and output from the row of third vias to determine an overall resistance of the conductive layer, the row of the first vias, and the row of third vias.

10. The resistive device of claim 9, wherein a second voltage signal across the conductive layer, the row of the first vias, and the row of the third vias is measured with the row of first vias and the row of third vias.

11. A semiconductor device, comprising:
a first resistor comprising:
a first conductive structure having a first side and a second side opposite to the first side; and
a first array of vias disposed closer to the first side than the second side; and
a second resistor comprising:
a second conductive structure having a third side and a fourth side opposite to the third side; and
a second array of vias disposed closer to the third side than the fourth side,
wherein the first conductive structure of the first resistor comprises a first conductive layer and the second conductive structure of the second resistor comprises a second conductive layer having a dimension different from that of the first conductive layer.

12. The semiconductor device of claim 11, wherein the dimension of the second conductive layer is twice as long as that of the first conductive layer.

13. The semiconductor device of claim 12, wherein the dimension of the second conductive layer is a ratio of a length of the second conductive layer to a width of the second conductive layer.

14. The semiconductor device of claim 11, further comprising a first back-end-of-line (BEOL) element and a second BEOL element, wherein the first resistor is electrically connected to and disposed between the first BEOL element and the second BEOL element.

15. The semiconductor device of claim 14, further comprising an active region disposed below the first resistor, wherein the second BEOL element is at an elevation higher than that of the first BEOL element with respect to the active region.

16. The semiconductor device of claim 11, wherein a contribution of a resistance of the first array of vias to a resistance of the first resistor is decreased as a number of rows of vias in the first array of vias is increased.

17. The semiconductor device of claim 11, wherein the first resistor and the second resistor are disposed in different arrays of resistors.

18. The semiconductor device of claim 11, wherein the first resistor and the second resistor are disposed in an array of resistors.

19. A method of obtaining electrical characteristics of a semiconductor device, comprising:
measuring, by a measurement tool, a first property of a first component of the semiconductor device comprising a number of first conductive vias and a first conductive layer;
measuring, by the measurement tool, a second property of a second component of the semiconductor device comprising a number of second conductive vias and a second conductive layer; and
calculating, by the measurement tool, a third property of the first conductive vias based on a first linear relationship associated with the first property and the second property,
wherein a dimension of the second conductive layer is different from that of the first conductive layer and a dimension of the first conductive vias is substantially identical to that of the second conductive vias.

20. The method of claim 19, further comprising calculating, by the measurement tool, a fourth property of the first conductive layer based on a second linear relationship associated with the first property and the third property.
